(19) United States
(12) Patent Application Publication
(10) Pub. No.: US 2006/0061979 A1
(43) Pub. Date: Mar. 23, 2006

(54) Substrate carrier having reduced height

(75) Inventors: Martin R. Elliott, Pepperell, MA (US); Michael R. Rice, Pleasanton, CA (US)

Correspondence Address: DUGAN & DUGAN, PC, 55 SOUTH BROADWAY, TARRYTOWN, NY, 10591, US

(73) Assignee: APPLIED MATERIALS, INC.

(21) Appl. No.: 11/219,332

(22) Filed: Sep. 2, 2005

Related U.S. Application Data
(60) Provisional application No. 60/607,283, filed on Sep. 4, 2004.

(51) Int. Cl. G06F 19/00; H05K 7/04

(52) U.S. Cl. 361/807

(57) ABSTRACT

A first substrate carrier is provided that includes a body adapted to store one or more substrates; and either (1) a bottom surface having one or more coupling features that extend into a storage region of the body or (2) coupling features that extend alongside the body, so that the substrate carrier's overall height is not increased by the entire height of the coupling feature. Numerous other aspects are provided.

This application claims priority from U.S. Provisional Patent Application Ser. No. 60/607,283, filed Sep. 4, 2004, which is hereby incorporated by reference herein in its entirety.

### FIELD OF THE INVENTION

The present invention relates generally to semiconductor device manufacturing, and more particularly to a substrate carrier having reduced height.

### BACKGROUND

Manufacturing of semiconductor devices typically involves performing a sequence of procedures with respect to a substrate such as a silicon substrate, a glass plate, etc. These steps may include polishing, deposition, etching, photolithography, heat treatment, and so forth. Usually a number of different processing steps may be performed in a single processing system or “tool” which includes a plurality of processing chambers. However, it is generally the case that other processes are required to be performed at other processing locations within a fabrication facility, and it is accordingly necessary that substrates be transported within the fabrication facility from one processing location to another. Depending on the type of semiconductor device to be manufactured, there may be a relatively large number of processing steps required, to be performed at many different processing locations within the fabrication facility.

It is conventional to transport substrates from one processing location to another within substrate carriers such as sealed pods, cassettes, containers and so forth. Many types of substrate carrier designs exist, but generally conventional substrate carriers are designed in a manner that unnecessarily increases the size (e.g., height) of such carriers. Clearance requirements for transporting such carriers and the space required to stack/store such carriers thereby increase.

### SUMMARY OF THE INVENTION

In a first aspect of the invention, a substrate carrier includes (1) a body adapted to store one or more substrates; and (2) a bottom surface having one or more coupling features that do not increase an overall height of the substrate carrier.

In a second aspect of the invention, a substrate carrier includes (1) a body for storing one or more substrates, the body having a substrate storage region for storing a substrate; and (2) a bottom surface having one or more coupling features adapted to extend into the substrate storage region outside of a footprint that would be occupied by a substrate positioned in the substrate storage region.

In a third aspect of the invention, an apparatus is provided that includes a plurality of stacked support shelves. Each support shelf is adapted to support a small lot size substrate carrier. The support shelves are spaced a distance from each other that allows only small lot size substrate carriers to be transported between the support shelves. The small lot size substrate carriers have (1) a body adapted to store one or more substrates; and (2) a bottom surface having one or more coupling features that do not increase an overall height of the substrate carrier.

In a fourth aspect of the invention, an apparatus is provided that includes a plurality of stacked support shelves. Each support shelf is adapted to support a small lot size substrate carrier. The support shelves are spaced a distance from each other that allows only small lot size substrate carriers to be transported between the support shelves. The small lot size substrate carriers have (1) a body for storing one or more substrates, wherein the body has a substrate storage region for storing a substrate; and (2) a bottom surface having one or more coupling features adapted to extend into the substrate storage region outside of a footprint that would be occupied by a substrate positioned in the substrate storage region.

In a fifth aspect of the invention, an end effector includes (1) a top surface; and (2) one or more coupling features on the top surface thereof, adapted to couple to the coupling features of the substrate carrier of the first apparatus.

In a sixth aspect of the invention, an end effector includes (1) a top surface; and (2) one or more coupling features on the top surface thereof, adapted to couple to the coupling features of the substrate carrier of the second apparatus. Numerous other aspects are provided in accordance with these and other aspects of the invention.

Other features and aspects of the present invention will become more fully apparent from the following detailed description, the appended claims and the accompanying drawings.

### BRIEF DESCRIPTION OF THE FIGURES

FIG. 1 is an isometric view of a bottom surface of a conventional substrate carrier.

FIG. 2 is a cross-sectional side view of a conventional substrate carrier.

FIG. 3A is an exploded isometric view of a substrate carrier in accordance with an embodiment of the present invention with a top portion removed.

FIG. 3B is an isometric view of a bottom surface of a substrate carrier in accordance with an embodiment of the present invention.

FIG. 4 is a first cross-sectional side view of a substrate carrier in accordance with an embodiment of the present invention.

FIG. 5 is a second cross-sectional side view of a substrate carrier in accordance with an embodiment of the present invention.

FIG. 6 is a bottom view of a substrate carrier in accordance with an embodiment of the present invention.

FIG. 7 is an isometric view of an end effector and a substrate carrier in accordance with an embodiment of the present invention.

FIG. 8 is an isometric view of the end effector and the substrate carrier of FIG. 7 shown interfacing in accordance with an embodiment of the present invention.

FIG. 9 is a front elevational view of a system for storing and/or docking a substrate carrier in accordance with an embodiment of the present invention.

FIG. 10 is an isometric view of a bottom surface of a substrate carrier in accordance with an alternative embodiment of the present invention.

FIG. 11 is a cross-sectional side view of a substrate carrier in accordance with an alternative embodiment of the present invention.

FIG. 12 is a bottom view of a substrate carrier in accordance with an embodiment of the present invention.

FIG. 13 is an isometric view of an end effector and a substrate carrier in accordance with an alternative embodiment of the present invention.

FIG. 14 is a cross-sectional side view of the end effector and the substrate carrier of FIG. 13 shown interfacing in accordance with an alternative embodiment of the present invention.

### DETAILED DESCRIPTION

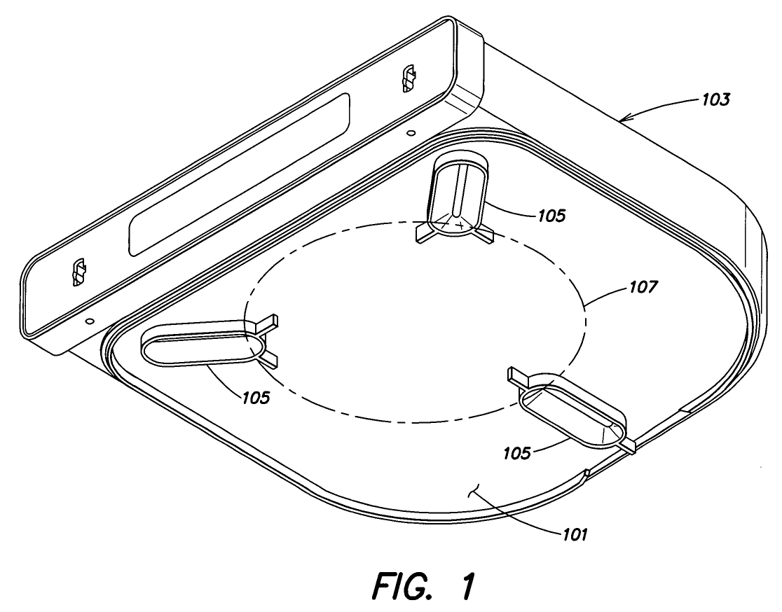

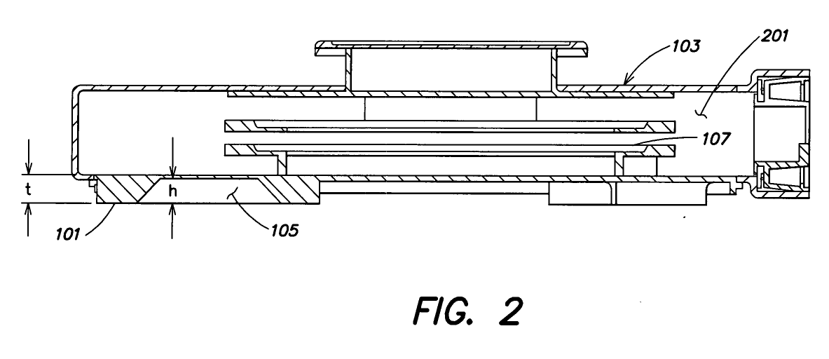

The present invention provides an improved substrate carrier. More specifically, in contrast to a conventional substrate carrier, which is described below with reference to FIGS. 1 and 2, the present invention provides a substrate carrier which more efficiently uses the space occupied by the substrate carrier.

FIG. 1 is an isometric view of a bottom surface 101 of a conventional substrate carrier 103. With reference to FIG. 1, the bottom surface 101 of the conventional substrate carrier 103 includes three V-shaped grooves 105. The V-shaped grooves 105 are adapted to couple to corresponding portions of a substrate carrier support (not shown). The V-shaped grooves 105 are positioned such that the V-shaped grooves 105 overlap a footprint of a substrate 107 (shown in phantom) stored in a storage region (not shown in FIG. 1; shown as 201 in FIG. 2) of the conventional substrate carrier 103.

FIG. 2 is a cross-sectional side view of a conventional substrate carrier. With reference to FIG. 2, the bottom surface 101 of the conventional substrate carrier is of a thickness t at least as high as a height h of the V-shaped grooves 105. Such thickness contributes to the overall space occupied by (e.g., height of) the conventional substrate carrier 103 and does not extend into the storage region 201. Therefore, the space occupied by the conventional substrate carrier 103 is used inefficiently.

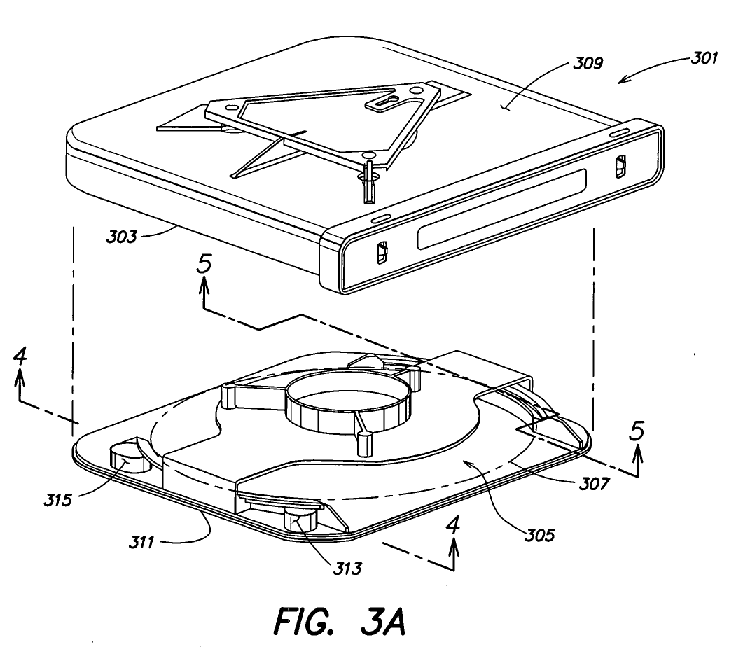

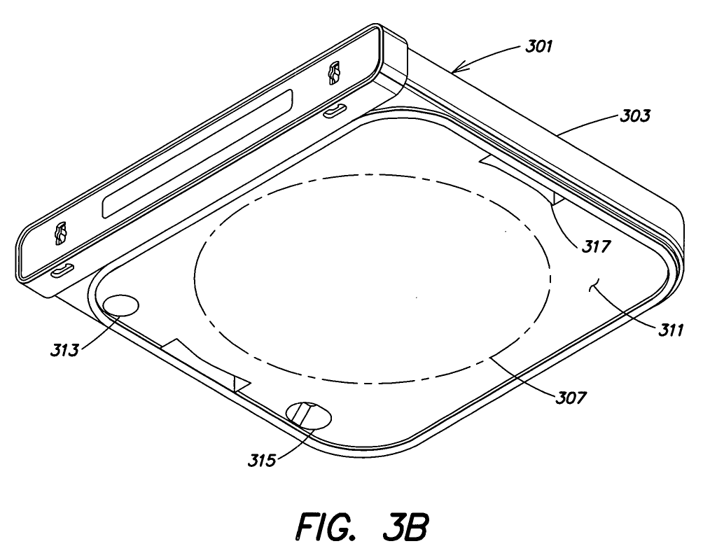

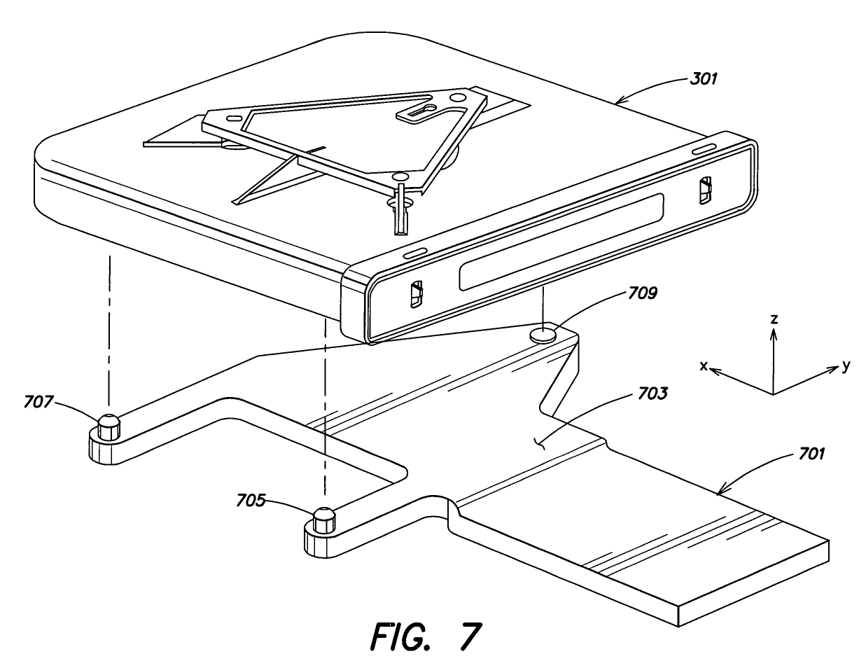

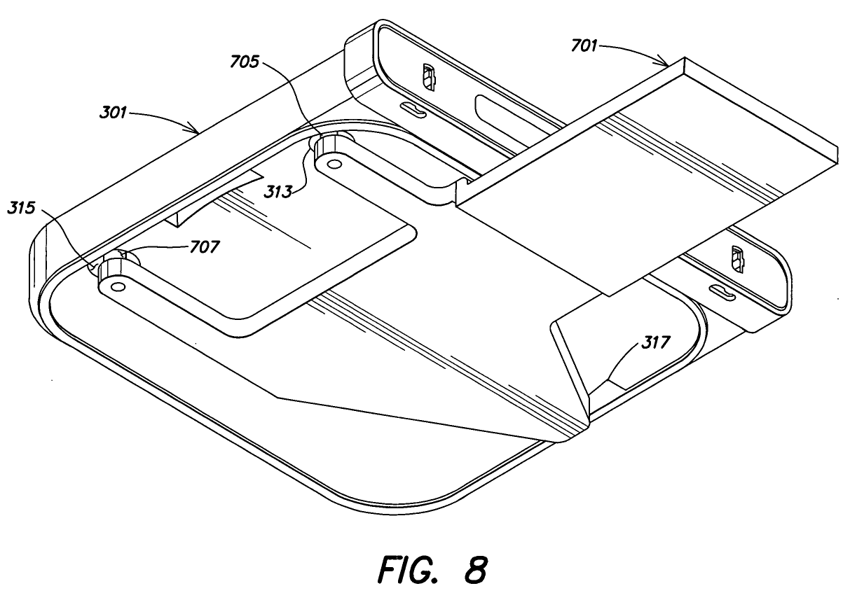

FIG. 3A is an exploded isometric view of a substrate carrier 301 in accordance with an embodiment of the present invention. With reference to FIG. 3A, the substrate carrier 301 includes a body 303 for storing one or more substrates. The body 303 includes a storage region 305 in which one or more substrates 307 (shown in phantom) may be stored. The body 303 further includes a top surface 309 and a bottom surface 311. In contrast to a conventional substrate carrier, the bottom surface 311 of the substrate carrier 301 includes one or more coupling features 313-317 adapted to extend into the storage region 305 outside a footprint that would be occupied by a substrate positioned in the storage region 305. For example, the one or more coupling features 313, 315, 317 (shown in FIG. 3B) occupy a position along a periphery of a footprint of a substrate 307 that may be stored in the storage region 305. The one or more coupling features 313-317 may couple to corresponding features of a substrate carrier support, such as an end effector (not shown FIG. 3A; shown as 401 in FIG. 4 and as 701 in FIGS. 7-8). In one embodiment, the one or more coupling features includes a hole, a slot and at least one surface for receiving a pad. However, a larger or smaller number, different shapes and/or different orientations of coupling features may be employed. For example, in some embodiments, the one or more coupling features include the hole 313 and slot 315 as described above. In such embodiments, a portion of the bottom surface 311 of the substrate carrier 301, which does not extend into the storage region 305 as described above, may be adapted to couple to a pad included on an end effector surface that supports the substrate carrier 301. Details of the one or more coupling features 313-317 are described below with reference to FIGS. 4-7.

Note that the substrate carrier 301 may be single piece or multi-piece construction (as shown). In one or more embodiments, the feature 317 may merely serve to keep cross sections of the carrier at an approximately constant thickness (e.g., for molding purposes), rather than as a kinematic coupling. The coupling features 313-317 may be, for example, conical or otherwise shaped to provide a large capture window during kinematic coupling.

FIG. 3B is an isometric view of a bottom surface of the substrate carrier 301 in accordance with an embodiment of the present invention. With reference to FIG. 3B, the bottom surface 311 of the substrate carrier 301 includes a hole 313 and a slot 315 that extend into a storage region outside a footprint that would be occupied by a substrate 307 (shown in phantom) positioned in the storage region. The bottom surface 311 of the substrate carrier may also include a region (e.g., slot) 317, which extends into the storage region outside a footprint that would be occupied by a substrate 307, for receiving an end effector pad.

FIG. 4 is a first cross-sectional side view of the substrate carrier 301 of FIG. 3A taken along line 4-4 of FIG. 3A and illustrates a hole 313 included (e.g., embedded) in the bottom surface 311 of the substrate carrier 301. The substrate carrier 301 is shown interfacing with an end effector 401. The hole 313 may be a height h1 of about 11 mm and may be conical (although, the bottom surface 311 may include a hole 313 of a larger or smaller height and/or a different shape). One or more portions of the hole 313 extends into storage region 305. Therefore, in contrast to a conventional substrate carrier 103 (FIG. 1), the thickness h2 of the bottom surface 311 that extends below the storage region 305 does not need to be at least as high as the hole 313. Similarly, a slot 315 is included (e.g., embedded) in the bottom surface 311 of the substrate carrier 301. The slot 315 may be a height h3 of about 11 mm and may be conical. (The slot 315, however, may be of a larger or smaller height and/or a different shape). Similar to the hole 313, one or more portions of the slot 315 extends into storage region 305. Therefore, in contrast to a conventional substrate carrier 103 (FIG. 1), the thickness h2 of the bottom surface 311 that extends below the storage region 305 does not need to be at least as high as the slot 315. In this manner, an overall space (e.g., height h4) occupied by the substrate carrier 301 may be reduced compared to that of a conventional substrate carrier 103.

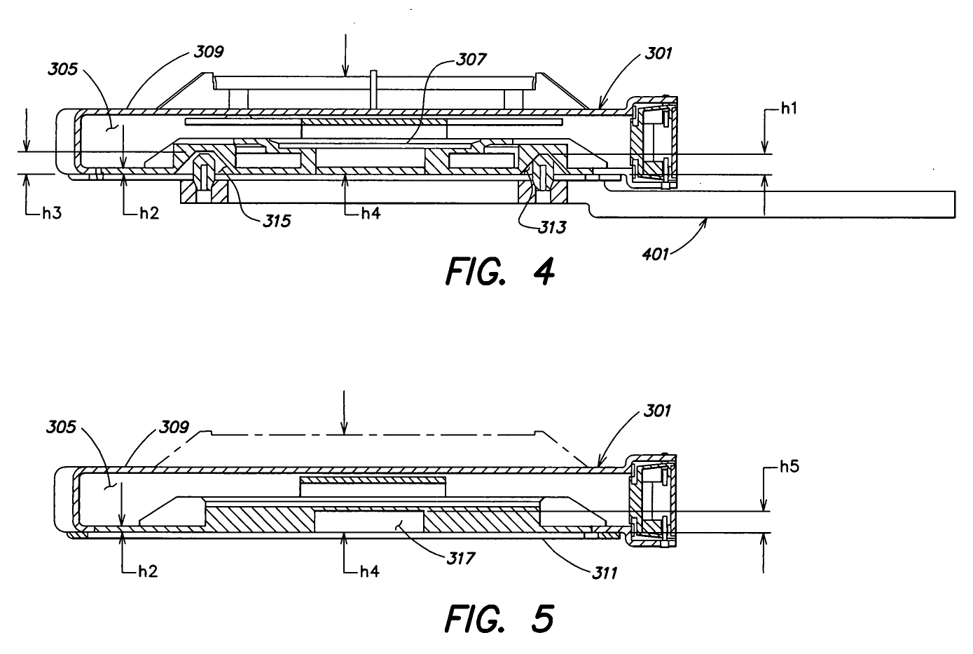

FIG. 5 is a second cross-sectional side view of the substrate carrier 301 of FIG. 3A taken along line 5-5 of FIG. 3A, and illustrates a region 317 (e.g., a groove or slot) for receiving a pad of an end effector as described further below. The region 317 is included (e.g., embedded) in the bottom surface 311 of the substrate carrier 301. The region 317 may be of a height h5 of about 11 mm and may be flat. However, the region 317 may be of a larger or smaller height and/or a different shape). Similar to the hole 313, one or more portions of the region 317 may extend into storage region 305. Therefore, in contrast to a conventional substrate carrier 103 (FIG. 1), the thickness h2 of the bottom surface 311 that extends below the storage region 305 does not have to be at least as high at the region 317, and consequently, an overall space (e.g., height h4) occupied by the substrate carrier 301 may be reduced as compared to a conventional substrate carrier 103 (FIG. 1).

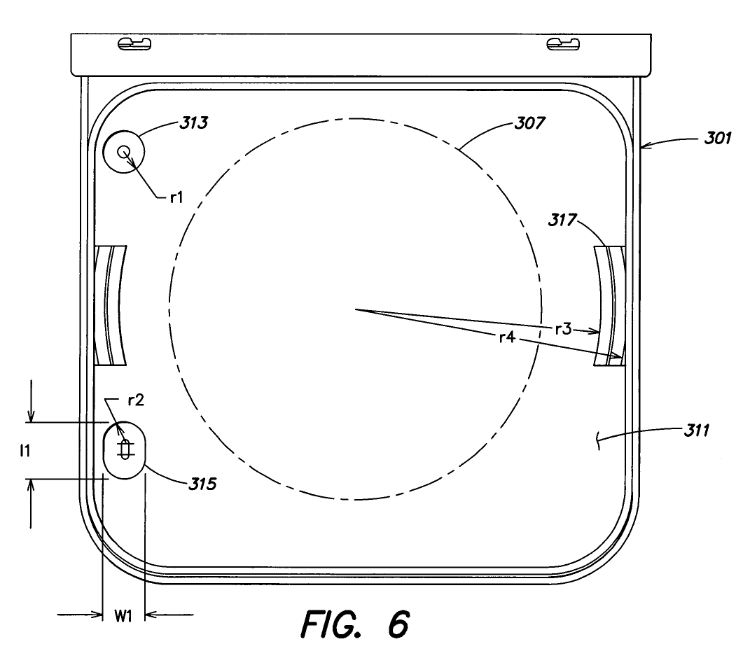

FIG. 6 is a bottom view of a substrate carrier 301 in accordance with an embodiment of the present invention. With reference to FIG. 6, the radius r1 of the hole 313 on the bottom surface 311 of the substrate carrier 301 is about 12.7 mm (although, the radius of the hole 313 may be larger or smaller). On the bottom surface 311 of the substrate carrier 301, the slot 315 has a width w1 of about 25.4 mm, a length 11 of about 33 mm and a radius r2 of about 12.7 mm (although, the slot 315 may be of a larger or smaller width w1, length 11 and/or radius r2). Further, in embodiments which include a region 317, which extends into the storage area 305, the region 317 may have an inner radius r3 of about 147.3 mm, an outer radius r4 of about 157.5 mm and a length of about 40 mm. However, the region 317 may have a larger or smaller inner radius, outer radius and/or length.

FIG. 7 is an isometric view of an end effector 701 and a substrate carrier 301 in accordance with an embodiment of the present invention. With reference to FIG. 7, the substrate carrier 301 is adapted to interface with the end effector 701. For example, the substrate carrier 301 may be coupled to, supported by and/or moved by the end effector 701. More specifically, the one or more coupling features 313-317 of the substrate carrier 301 may couple to corresponding features (e.g., posts, pins and/or pads) extending from a top surface 703 of the end effector 701. More specifically, the hole 313 and slot 315 on the bottom surface 311 of the substrate carrier 301 may couple to corresponding posts 705, 707 on the end effector 701. In some embodiments, such corresponding posts 705, 707 on the end effector 701 may be conical or spherical. The region 317 in the bottom surface 311 of the substrate carrier 301 may couple to a corresponding pin or pad 709 on the end effector 701. The corresponding pin or pad 709 may be, for example, a flat-headed pin. The one or more coupling features 313-317 of the substrate carrier 301 and/or the corresponding features 705-709 of the end effector 701 may be kinematic features, adapted to kinematically align the substrate carrier 301 with the end effector 701, thereby ensuring that the substrate carrier 301 properly rests on the end effector 701. For example, the hole 313 may align the substrate carrier 301 with the end effector 701 along the x and y axes; the slot 315 may prevent the substrate carrier 301 from rotating on the end effector 701 in the xy-plane; and the region 317 may prevent movement of the substrate carrier 301 along the z-axis. In some embodiments in which the substrate carrier 301 does not include a region 317, which extends into the storage region, a portion of the bottom surface 311 of the substrate carrier 301 may contact the pad 709 and prevent the substrate carrier 301 from moving along the z-axis (as well as to prevent rotation about the axis formed by the posts 705 and/or 707).

FIG. 8 is an isometric view of the end effector 701, shown interfacing with the substrate carrier 301 of FIG. 7 in accordance with an embodiment of the present invention. More specifically, coupling features 313-317 on the bottom surface 311 of the substrate carrier 301 receive and/or couple to coupling features 705-709 of the end effector 701, thereby aligning the substrate carrier 301 with the end effector 701 and ensuring the end effector 701 properly supports the substrate carrier 301.

The one or more coupling features 313-317 of the substrate carrier 301 may be adapted to interface with any other device for supporting the substrate carrier 301 (in a addition to an end effector). For example, the one or more coupling features 313-317 may be adapted to couple to corresponding coupling features of a support shelf, a load port, or the like, thereby aligning the substrate carrier 301 therewith.

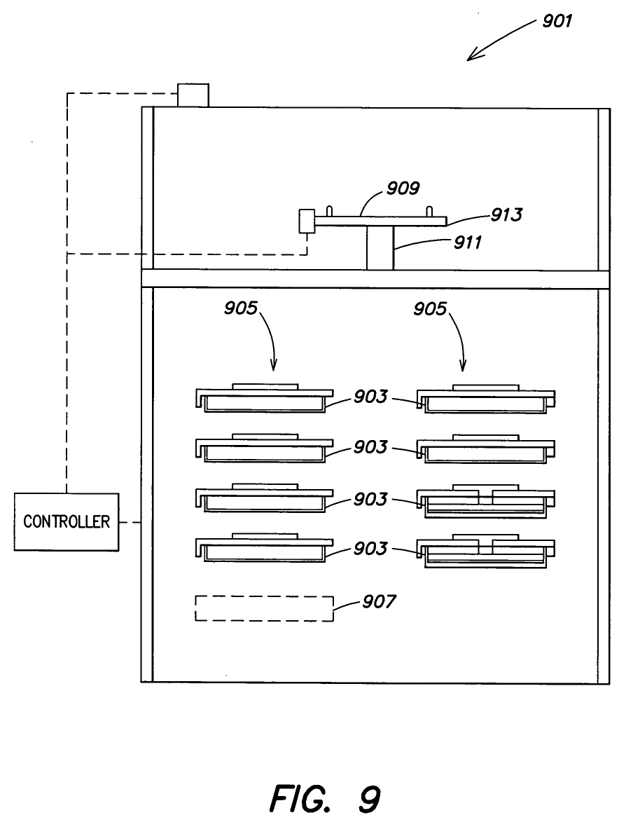

FIG. 9 is a front elevational view of a system 901 for storing and/or docking (e.g., positioning a substrate carrier at a tool load port for door opening and substrate removal) a substrate carrier in accordance with an embodiment of the present invention. With reference to FIG. 9, the system 901 may be employed for loading a substrate into a semiconductor device manufacturing tool (not shown). The system 901 may include one or more load ports or similar locations where substrates or substrate carriers (e.g., small lot size substrate carriers) are placed for transfer to and/or from a processing tool (e.g., one or more docking stations 903, although transfer locations that do not employ docking/undocking movement may be employed).

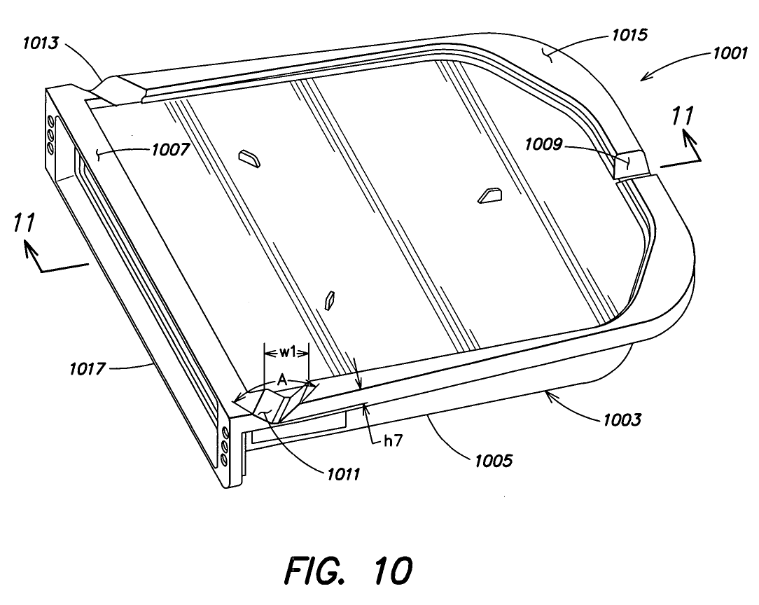

In one aspect, the one or more load ports or similar locations may be spaced a distance from each other such that only the substrate carrier 301 (or the substrate carrier 1001 of FIGS. 10-14 described below) may be transported between such locations. In the particular embodiment shown, the system 901 includes a total of eight docking stations 903, arranged in two columns 905 of four docking stations each. Other numbers of columns and/or docking stations 903 may be employed. Each docking station 903 is adapted to support and/or dock a substrate carrier in accordance with an embodiment of the present invention at the docking station 903 and to allow a substrate (not shown) to be extracted from the substrate carrier at the docking station 903 and transferred to the processing tool (not shown). The system 901 may include one or more storage shelves or other storage locations (e.g., storage shelf 907, shown in phantom, adapted to store a substrate carrier in accordance with an embodiment of the present invention). The system may include an end effector 909 mounted on a support 911. The end effector 909 may be, for example, in the form of a horizontally-oriented platform 913 adapted to support the substrate carrier in accordance with an embodiment of the present invention. More specifically, the system 901 may be similar to the wafer loading station 201 of U.S. patent application Ser. No. 10/650,480, filed Aug. 28, 2003 and titled “Substrate Carrier Handler That Unloads Substrate Carriers Directly From a Moving Conveyor” (Attorney Docket No. 7676), which is hereby incorporated by reference herein in its entirety. However, similar to the end effector 701 of FIG. 8, the load ports (e.g., docking stations 903), support shelves 907 (only one shown) and/or end effector 909 of the system 901 may include coupling features (e.g., posts, pads or pins) for interfacing with the one or more coupling features on the bottom surface of the substrate carrier 301 (or substrate carrier 1001 of FIGS. 10-14).

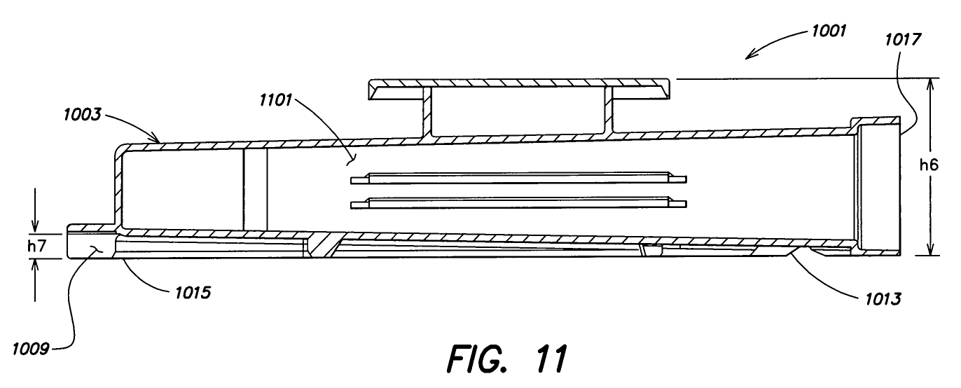

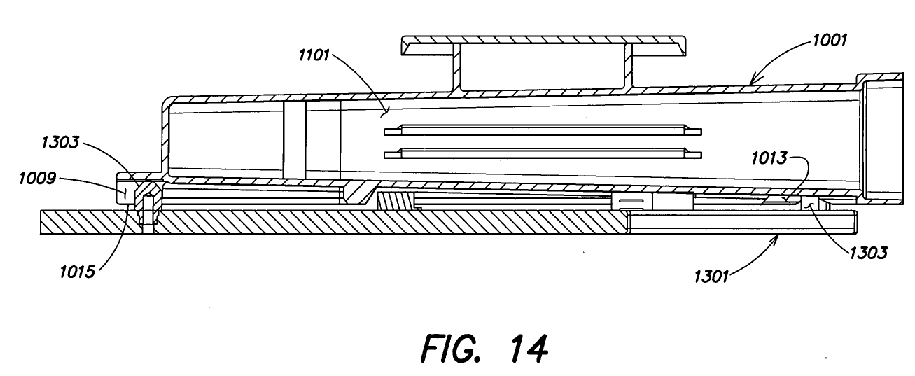

FIG. 10 is an isometric view of a bottom surface of a substrate carrier 1001 in accordance with an alternative embodiment of the present invention. With reference to FIG. 10, the substrate carrier 1001 includes a body 1003 adapted to store one or more substrates. The body 1003 includes a storage region (not shown in FIG. 10; shown as 1101 in FIGS. 11 and 14) in which the one or more substrates may be stored. The body 1003 further includes a top surface 1005 and a bottom surface 1007. In contrast to a conventional substrate carrier, the bottom surface 1015 of the substrate carrier 1001 includes one or more coupling features 1009-1013 that do not increase an overall height of the substrate carrier 1001. More specifically, the one or more coupling features 1009-1013 do not increase the overall height of the substrate carrier 1001 by extending below a plane defined by a bottom surface 1015 or base of the substrate carrier 1001. For example, the one or more coupling features 1009-1013 may not extend below the lowest point of a front face 1017 of the substrate carrier 1001. The one or more of the coupling features 1009-1013 are located outside a perimeter of the body 1003. In this manner, in contrast to the substrate carrier 301 of FIG. 3, the one or more coupling features 1009-1013 of the substrate carrier 1001 may not extend into the storage region (not shown in FIG. 10; shown as 1101 in FIGS. 11 and 14).

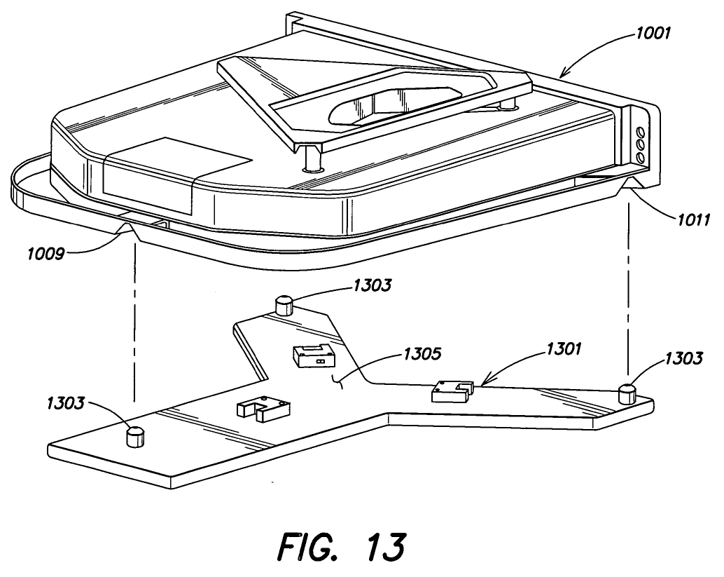

The one or more coupling features 1009-1013 may couple to corresponding features of a substrate carrier support, such as an end effector (not shown in FIG. 10; shown as 1301 in FIGS. 13-14). In one embodiment, the one or more coupling features 1009-1013 are slots, which are substantially V-shaped. A coupling feature 1009-1013 may be of a height h7 of about 0.47 in., a width w1 of about 1.1 in., form an angle A of about 90 degrees and the peak of the coupling feature 1009-1013 may have a radius of curvature of about 0.13 in. However, one or more coupling features may have a larger or smaller height, width, radius of curvature and/or form a larger or smaller angle A or have a different shape. For example, one or more coupling features 1009-1013 may be a hole. Although the substrate carrier 1001 of FIG. 10 includes three coupling features 1009-1013, a larger or smaller number of coupling features may be employed.

FIG. 11 is a cross-sectional side view of the substrate carrier 1001 taken along line 11-11 of FIG. 10 and illustrates how the one or more coupling features 1009-1013 do not increase the overall height h6 of the substrate carrier 1001 by extending below a plane defined by a bottom surface 1015 or base of the substrate carrier 1001. The one or more coupling features 1009-1013, in one aspect, may not extend below the lowest point of a front face 1017 of the substrate carrier 1001. This may be accomplished by placing the one or more coupling features 1009-1013 around a perimeter of the body 1003. Therefore, the one or more coupling features 1009-1013 (e.g., the coupling features 1011-1013 nearest the front face 1017) may extend alongside the body 1003 without extending into the storage region 1101 of the substrate carrier 1001. Thus the one or more couplings features are adapted to occupy a position along a periphery of a substrate stored in the body.

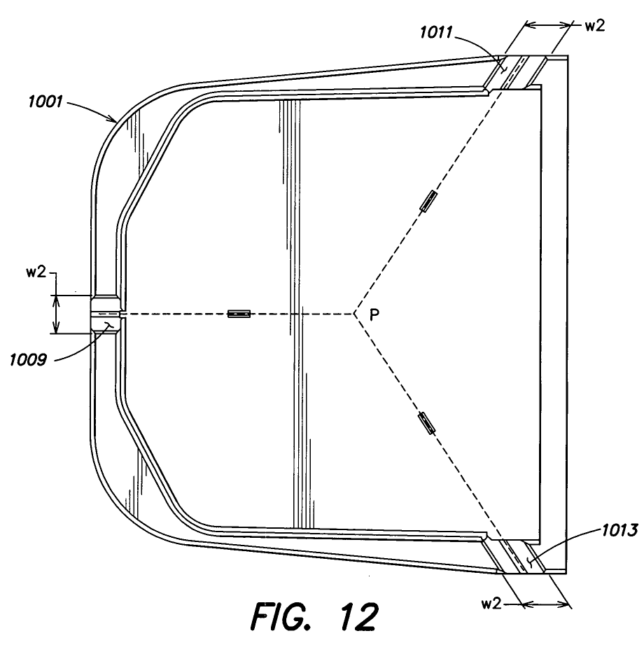

FIG. 12 is a bottom view of the substrate carrier 1001. In the embodiment of FIG. 12, the coupling features 1009-1013 may be positioned and/or oriented such that lines bisecting the width w2 of each coupling feature intersect at a point P. Other configurations may be employed.

FIG. 13 is an isometric view of an end effector 1301 and the substrate carrier 1001 in accordance with an alternative embodiment of the present invention. With reference to FIG. 13, the substrate carrier 1001 of FIG. 10 is adapted to interface with the end effector 1301. For example, the substrate carrier 1001 may be coupled to, supported by and/or moved by the end effector 1301. More specifically, the one or more coupling features 1009-1013 of the substrate carrier 1001 may couple to corresponding features 1303 (e.g., posts, pads, pins, etc.) extending from a top surface 1305 of the end effector 1301. Such corresponding features 1303 on the end effector 1305 may be conical or spherical or flat-headed, for example. The one or more coupling features 1009-1013 of the substrate carrier 1001 and/or the corresponding features 1303 of the end effector 1301 may be kinematic features, adapted to kinematically align the substrate carrier 1001 with the end effector 1301, thereby ensuring that the end effector 1301 properly supports the substrate carrier 1001.

FIG. 14 is a cross-sectional side view of the end effector 1301 and the substrate carrier 1001 of FIG. 13 shown interfacing. More specifically, coupling features 1009-1013 on the bottom surface 1015 of the substrate carrier 1001 receive and/or couple to coupling features 1303 of the end effector 1301, thereby aligning the substrate carrier 1001 with the end effector 1301 and ensuring the end effector 1301 properly supports the substrate carrier 1001.

Although FIGS. 13 and 14 illustrate how the substrate carrier 1001 may interface with the end effector 1301, the one or more coupling features 1009-1013 of the substrate carrier 1001 also may interface with any other device for supporting the substrate carrier 1001. For example, the one or more coupling features 1009-1013 may couple to corresponding coupling features of a support shelf, load port, or the like, thereby aligning the substrate carrier 1001 therewith.

The foregoing description discloses only exemplary embodiments of the invention. Modifications of the above disclosed apparatus and methods which fall within the scope of the invention will be readily apparent to those of ordinary skill in the art. For instance, although one or more embodiments of the present invention were described above with reference to a substrate carrier for storing one or two substrates, the present methods and apparatus may be employed with a substrate carrier that stores a larger number of substrates.

Any of the above described carriers may be have a single shell with kinematic features molded therein, or be of a multi-piece construction.

Accordingly, while the present invention has been disclosed in connection with exemplary embodiments thereof, it should be understood that other embodiments may fall within the spirit and scope of the invention, as defined by the following claims.

The invention claimed is:

1. A substrate carrier, comprising:
a body adapted to store one or more substrates, the body having a substrate storage region adapted to store a substrate; and
a bottom surface having one or more coupling features adapted to extend into the substrate storage region outside of a footprint that would be occupied by a substrate positioned in the substrate storage region.

2. The substrate carrier of claim 1, wherein all coupling features occupy the substrate storage region outside of a footprint that would be occupied by a substrate positioned in the substrate storage region.

3. The substrate carrier of claim 1, wherein the one or more coupling features are further adapted to occupy a position along a periphery of a substrate stored in the body.

4. The substrate carrier of claim 1, wherein the one or more coupling features are further adapted to kinematically couple with a corresponding feature on a surface adapted to support the substrate carrier.

5. The substrate carrier of claim 1, wherein the one or more coupling features include at least one of a hole, a slot and a feature to receive a pad.

6. The substrate carrier of claim 5, wherein at least one of the hole and slot is conical.

7. The substrate carrier of claim 5, wherein the pad is flat.

8. An apparatus, comprising:
a plurality of stacked support shelves, each support shelf adapted to support a substrate carrier, wherein the support shelves are spaced a distance from each other that allows transportation between the support shelves of only a substrate carrier, having a body adapted to store one or more substrates, the body having a substrate storage region adapted to store a substrate, and a bottom surface having one or more coupling features adapted to extend into the substrate storage region outside of a footprint that would be occupied by a substrate positioned in the substrate storage region.

9. The apparatus of claim 8 wherein at least one of the support shelves is a docking station adapted to open the substrate carrier and allow substrate extraction therefrom.

10. The apparatus of claim 8 wherein a plurality of the stacked support shelves are docking stations adapted to open the substrate carrier and allow substrate extraction therefrom.

11. The apparatus of claim 8 wherein the support shelves are spaced so as to allow transportation of only small lot size substrate carriers.

12. A substrate carrier, comprising:
a body adapted to store one or more substrates; and
a bottom surface having one or more coupling features located outside a perimeter of the body.

13. The substrate carrier of claim 12, wherein the one or more couplings features are further adapted so as to extend at least partially alongside the body so that at least part of the one or more coupling features does not extend below the body.

14. The substrate carrier of claim 12, wherein the one or more coupling features are further adapted to kinematically couple with a corresponding feature on a surface adapted to support the substrate carrier.

15. The substrate carrier of claim 12, wherein the one or more coupling features includes at least one of a hole and a slot.

16. The substrate carrier of claim 15, wherein at least one of the hole and slot is conical.

17. An apparatus, comprising:
a plurality of stacked support shelves, each support shelf adapted to support a substrate carrier, wherein the support shelves are spaced a distance from each other that allows transportation between the support shelves of only a substrate carrier having a body adapted to store one or more substrates and a bottom surface having one or more coupling features located outside the perimeter of the body.

18. The apparatus of claim 17 wherein at least one of the support shelves is a docking station adapted to open the substrate carrier and allow substrate extraction therefrom.

19. The apparatus of claim 17 wherein a plurality of the support shelves are docking stations adapted to open the substrate carrier and allow substrate extraction therefrom.

20. The apparatus of claim 17 wherein the support shelves are spaced so as to allow transportation of only small lot size substrate carriers.

21. An end effector, comprising:
a top surface having one or more coupling features adapted to couple to a substrate carrier having:
a body adapted to store one or more substrates, the body having a substrate storage region adapted to store a substrate; and
a bottom surface having one or more coupling features adapted to extend into the substrate storage region outside of a footprint that would be occupied by a substrate positioned in the substrate storage region.

22. An end effector, comprising:
a top surface having one or more coupling features adapted to couple to a substrate carrier having:
a body adapted to store one or more substrates; and
a bottom surface having one or more coupling features located outside a perimeter of the body.
